(19) United States
(12) Patent Application Publication
(10) Pub. No.: US 2015/0155460 A1
(43) Pub. Date: Jun. 4, 2015

(54) LIGHT-EMITTING APPARATUS

(71) Applicants: CITIZEN ELECTRONICS CO., LTD., Fujiyoshida-shi (JP); CITIZEN HOLDINGS CO., LTD., Tokyo (JP)

(72) Inventor: Koichi Fukasawa, Fujiyoshida-shi (JP)

(73) Assignees: CITIZEN ELECTRONICS CO., LTD., Fujiyoshida-shi (JP); CITIZEN HOLDINGS CO., LTD., Nishitokyo-shi (JP)

(21) Appl. No.: 14/552,787

(22) Filed: Nov. 25, 2014

(30) Foreign Application Priority Data
Nov. 29, 2013 (JP) 2013-248544

(51) Int. Cl. H01L 33/62; H01L 33/32; H01L 33/08; H01L 33/50; H01L 33/56

(52) U.S. Cl. CPC H01L 33/62; H01L 33/502; H01L 33/56; H01L 33/08; H01L 33/32

(57) ABSTRACT

A light-emitting apparatus that can produce white light that appears crisper by controlling light-emitting devices of different colors using a simplified wiring configuration is provided. The light-emitting apparatus includes a plurality of blue-emitting devices as blue-emitting semiconductor light-emitting devices, a plurality of green-emitting devices as green-emitting semiconductor light-emitting devices, and a sealing resin through which is dispersed a red phosphor that emits red light by absorbing blue light from the plurality of blue-emitting devices and green light from the plurality of green-emitting devices as pump light, the sealing resin covering the plurality of blue-emitting devices and the plurality of green-emitting devices, wherein the plurality of blue-emitting devices and the plurality of green-emitting devices are connected in series with each other.

### CROSS REFERENCE TO RELATED APPLICATION

This application is a new U.S. patent application that claims benefit of JP 2013-248544, filed on Nov. 29, 2013. The entire content of JP 2013-248544 is hereby incorporated by reference.

### TECHNICAL FIELD

The present invention relates to a light-emitting apparatus including semiconductor light-emitting devices.

### BACKGROUND ART

In recent years, light-emitting apparatus have been commercially implemented that produce white light by combining semiconductor light-emitting devices such as blue LEDs (light-emitting diodes), etc., with phosphors. Among others, light-emitting apparatuses are known which use two kinds of semiconductor light-emitting devices, i.e., blue and green LEDs, in combination with phosphors such as a red phosphor, etc., in order to produce white light having a natural hue (i.e., with good color rendering properties).

For example, Japanese Unexamined Patent Publication No. 2006-245443 discloses a light-emitting apparatus including a blue LED, a green LED, a yellow phosphor which emits yellow fluorescent light by absorbing blue light from the blue LED as pump light, and a red phosphor which emits red fluorescent light by absorbing green light from the green LED as pump light. On the other hand, Japanese Unexamined Patent Publication No. 2010-197840 discloses a liquid crystal display apparatus having a packaged white light source which produces white light by mixing blue light emitted from blue LED devices, green light emitted from green LED devices, and red light obtained by exciting a red phosphor with the blue and green lights. In this light source, the blue LED devices and the green LED devices are connected in parallel by using separate wiring lines, and the amount of light emission of each device is controlled independently of the other.

### SUMMARY

In a light-emitting apparatus having a blue-emitting device and a green-emitting device as light-emitting devices, the blue-emitting device and the green-emitting device are connected by using separate wiring lines, and the voltage and current applied to each color emitting device is controlled independently of the voltage and current applied to the other, as in the light source disclosed in Japanese Unexamined Patent Publication No. 2010-197840, in order to obtain white light of the desired hue. However, if the blue- and green-emitting devices are to be controlled for lighting independently of each other, two separate wiring lines will have to be provided. For example, when using such a light-emitting apparatus as a lighting apparatus, if the light-emitting devices of different colors are to be controlled for lighting independently of each other, the wiring and control for lighting the light-emitting devices of the respective colors becomes complex because the number of light-emitting devices of each color increases.

On the other hand, light-emitting apparatuses are known which produce white light without using any green-emitting device, but using a blue monochromatic LED in combination with phosphors of a plurality of colors such as a green phosphor and a red phosphor. However, in the case of a light-emitting apparatus using a monochromatic LED in combination with phosphors of a plurality of colors, a sufficient light emission intensity cannot be obtained because the phosphors of the different colors have to be excited with the monochromatic light, and besides, there arises a problem that color variations occur because the phosphors of the different colors are mixed. It is therefore desirable to minimize the number of kinds of phosphors to be used in the light-emitting apparatus.

In view of the above, it is an object of the present invention to provide a light-emitting apparatus that can produce white light that appears crisper by controlling light-emitting devices of different colors using a more simplified wiring configuration than it would appear if the configuration of the invention were not employed.

Provided is a light-emitting apparatus includes a plurality of blue-emitting devices as blue-emitting semiconductor light-emitting devices, a plurality of green-emitting devices as green-emitting semiconductor light-emitting devices, and a sealing resin through which is dispersed a red phosphor that emits red light by absorbing blue light from the plurality of blue-emitting devices and green light from the plurality of green-emitting devices as pump light, the sealing resin covering the plurality of blue-emitting devices and the plurality of green-emitting devices, wherein the plurality of blue-emitting devices and the plurality of green-emitting devices are connected in series with each other.

Preferably, in the above light-emitting apparatus, the plurality of blue-emitting devices and the plurality of green-emitting devices are both InGaN-based semiconductor light-emitting devices.

Preferably, in the above light-emitting apparatus, the plurality of blue-emitting devices and the plurality of green-emitting devices are grouped into a plurality of columns which are connected in parallel with each other on a single substrate, and wherein in each of the plurality of columns, a plurality of the blue-emitting devices and a plurality of the green-emitting devices are connected in series with each other.

Preferably, in the above light-emitting apparatus, the ratio of the number of the plurality of blue-emitting devices to the number of the plurality of green-emitting devices contained in each of the plurality of columns is the same for all of the columns.

The above light-emitting apparatus can produce white light that appears crisper by controlling light-emitting devices of different colors using a more simplified wiring configuration than it would appear if the configuration of the invention were not employed.

### BRIEF DESCRIPTION OF THE DRAWINGS

Other features and advantages of the present invention will be apparent from the ensuing description, taken in conjunction with the accompanying drawings, in which:

FIGS. 1A and 1B are a schematic top plan view and a cross-sectional view of a light-emitting apparatus 10;

FIGS. 2A and 2B are wiring diagrams showing connection examples of the blue LEDs 11 and green LEDs 12;

FIG. 3 is a diagram of graphs schematically depicting the temperature characteristics of the respective color LEDs;

FIG. 4A is a graph illustrating the spectrum of white light produced by a light-emitting apparatus of a comparative example;

FIG. 4B is a graph illustrating the spectrum of white light produced by the light-emitting apparatus 10;

FIG. 5 is a schematic cross-sectional view of a light-emitting apparatus 20; and

FIG. 6 is a schematic cross-sectional view of a light-emitting apparatus 30.

### DESCRIPTION

Hereinafter, with reference to the drawings, a light-emitting apparatus will be described. It should be noted that the technical scope of the present invention is not limited to embodiments of the invention, but covers the invention described in the claims and its equivalent.

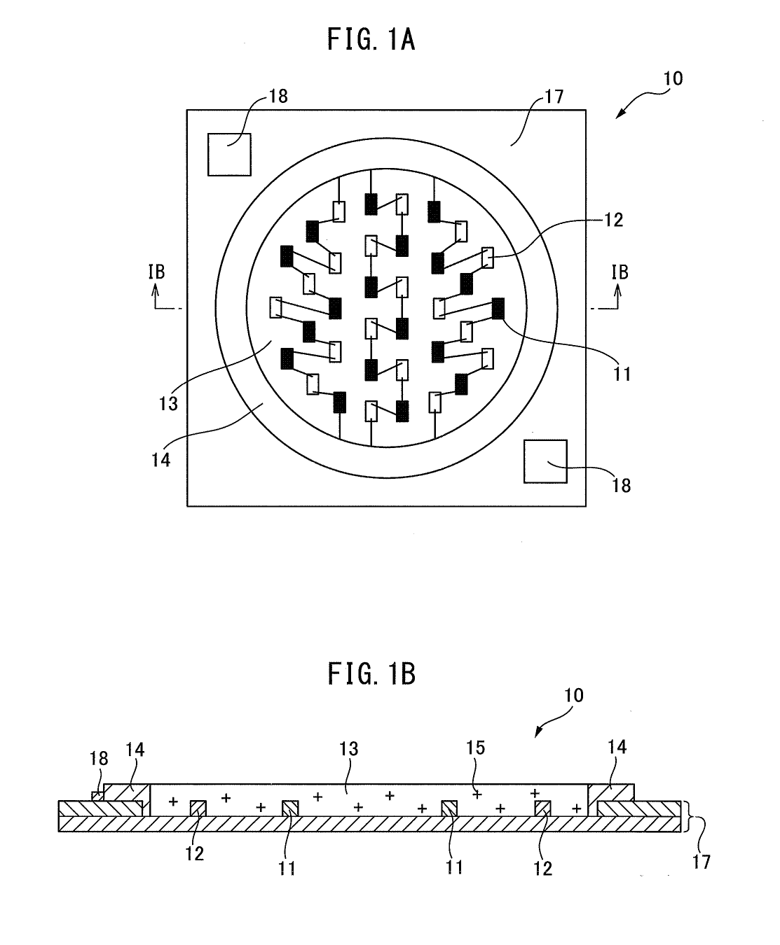

FIG. 1A is a schematic top plan view of a light-emitting apparatus 10. FIG. 1B is a cross-sectional view taken along line IB-IB in FIG. 1A.

The light-emitting apparatus 10 includes a plurality of blue LEDs 11, a plurality of green LEDs 12, a sealing resin 13, a sealing frame 14, a substrate 17, and electrodes 18. In the light-emitting apparatus 10, the plurality of blue LEDs 11 and the plurality of green LEDs 12 are together covered with the sealing resin 13 containing a red phosphor 15. With this configuration, the light-emitting apparatus 10 produces white light by mixing blue light from the blue LEDs 11, green light from the green LEDs 12, and red light obtained by exciting the red phosphor 15 with the blue and green lights.

Each blue LED 11 is a blue-emitting semiconductor light-emitting device (blue-emitting device) constructed using, for example, an InGaN-based compound semiconductor whose emission wavelength is in the range of 450 to 460 nm. Each green LED 12 is a green-emitting semiconductor light-emitting device (green-emitting device) constructed using, for example, an InGaN-based compound semiconductor whose emission wavelength is in the range of 510 to 530 nm. It is preferable that LEDs that can be regarded as having substantially the same forward voltage (VF), temperature characteristics, and service life be used for the blue LEDs 11 and green LEDs 12, respectively. In view of this, it is preferable to construct the blue LEDs 11 and green LEDs 12 by using compound semiconductors based on the same materials. For example, if InGaN-based compound semiconductors prepared by varying the In/Ga mixing ratio are used for the blue LEDs 11 and green LEDs 12, respectively, each of the LEDs will have approximately the same forward voltage which is about 3.5 V.

The sealing resin 13 is a colorless, transparent resin such as an epoxy resin or silicone resin, and is applied to cover the blue LEDs 11 and green LEDs 12 in an integral fashion. The red phosphor 15 is dispersed in the form of particles through the sealing resin 13. The sealing resin 13 is molded into an appropriate shape (in the example of FIG. 1A, a circular shape) according to the purpose of the light-emitting apparatus 10, and is held fixedly on the substrate 17 by the sealing frame 14 which is, for example, made of plastic.

The red phosphor 15 is a particulate phosphor material that emits red light by absorbing the blue light from the blue LEDs 11 and the green light from the green LEDs 12 as pump light. For example, a CaAlSiN₃ (calcium aluminum silicon trinitride) phosphor doped with Eu²⁺ (europium) as a solid solution may be used as the red phosphor 15. The CaAlSiN₃ phosphor doped with Eu²⁺ as a solid solution is a phosphor which, when excited with pump light ranging from blue to green light, emits red light with a high emission intensity comparable, for example, to that of a red phosphor of yttrium oxide which emits light when excited with ultraviolet light, and is preferred for use as the red phosphor 15.

The substrate 17 is an insulating substrate, such as a glass epoxy substrate, BT resin substrate, ceramic substrate, metal core substrate, or the like, on the surface of which the blue LEDs 11 and green LEDs 12 are mounted. Connecting electrodes (not shown) to the blue LEDs 11 and green LEDs 12 and a circuit pattern (not shown) are formed on the substrate 17. The electrodes of the blue LEDs 11 and green LEDs 12 are electrically connected to the connecting electrodes on the substrate 17 via an electrically conductive adhesive material, such as Ag paste, and wires formed by wire bonding.

The electrodes 18 are provided to connect the substrate 17 to an external DC power supply. In the light-emitting apparatus 10, the plurality of blue LEDs 11 and green LEDs 12 are arranged in the form of an array on the single substrate 17 to form one package, and the electrodes 18 are provided as its two terminals.

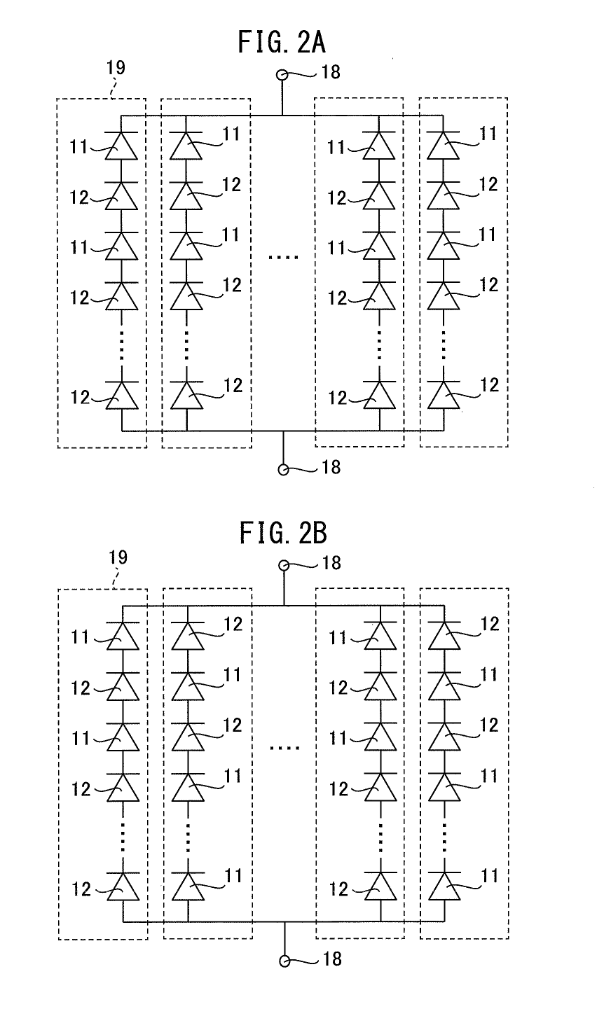

FIGS. 2A and 2B are wiring diagrams showing connection examples of the blue LEDs 11 and green LEDs 12. In the light-emitting apparatus 10, the blue LEDs 11 and the green LEDs 12 are not connected separately from each other, but are connected in series with each other as indicated by reference numeral 19 in FIGS. 2A and 2B. Then, a plurality of series connections 19 (also referred to simply as “columns 19”) of the blue LEDs 11 and green LEDs 12 are connected in parallel with each other to form a series-parallel circuit. Each series connection 19 includes, for example, a total of twelve blue and green LEDs 11 and 12, and twelve such series connections 19 are connected in parallel, thus a total of 144 LEDs constituting the light-emitting apparatus 10.

In order to obtain uniform white light, it is preferable that the blue LEDs 11 and green LEDs 12 be connected, for example, in alternating fashion in each column 19. For example, the blue LEDs 11 and green LEDs 12 may be connected in the same order in all the columns 19, as shown in FIG. 2A, or the ordering may be changed from one column 19 to the next or may be reversed between adjacent columns 19 (so as to arrange the respective color LEDs in a checkerboard pattern) as shown in FIG. 2B.

Further, in order to reduce the variation in current from one column 19 to the next, it is preferable that the ratio of the number of blue LEDs 11 to the number of green LEDs 12 be the same for all the columns 19. For example, the ratio of the number of blue LEDs 11 to the number of green LEDs 12 may be 1:1 (six each) for each column 19. Alternatively, considering the fact that the emission intensity of the green LEDs 12 is lower than that of the blue LEDs 11, the number of green LEDs 12 may be made larger than the number of blue LEDs 11, for example, the ratio of the number of blue LEDs 11 to the number of green LEDs 12 may be 5:7. Conversely, depending on the required hue of the white light, the number of blue LEDs 11 may be made larger than the number of green LEDs 12.

With the above series-parallel circuit, when a voltage exceeding the combined forward voltage (about 38 V) of twelve LEDs, for example, is applied in the light-emitting apparatus 10, the blue LEDs 11 and green LEDs 12 all turn on. These LEDs are either all ON or all OFF, and behave as if there were one large LED. Strictly speaking, the forward voltage of a blue LED 11 and the forward voltage of a green LED 12 are not the same but, by choosing LEDs that can be regarded as having substantially the same forward voltage, it is possible to connect the blue LEDs 11 and green LEDs 12 in series with each other. When the blue LEDs 11 and green LEDs 12 are connected in series, the control of each color LED is simplified because the current flowing in each color LED is the same.

Another possible method to simplify the control of the voltage and current applied to each color LED is to replace the red phosphor 15 by red LEDs whose emission wavelength is in the red wavelength range and to connect the blue LEDs 11, green LEDs 12, and red LEDs in series with each other as in the above-described columns 19. However, while generally, blue LEDs and green LEDs have similar temperature and lifetime characteristics, the temperature and lifetime characteristics of red LEDs are substantially different from those of the blue LEDs and green LEDs, as will be described hereinafter.

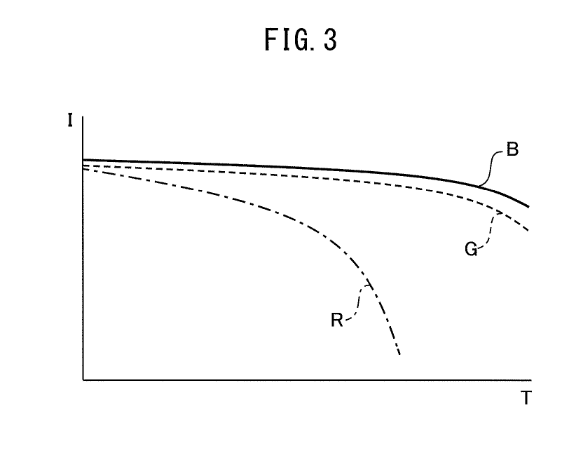

FIG. 3 is a diagram of graphs schematically depicting the temperature characteristics of the respective color LEDs. In FIG. 3, the abscissa represents the temperature T which increases in the rightward direction along the abscissa. The ordinate represents the emission intensity I which increases in the upward direction along the ordinate. In FIG. 3, solid line B, dashes line G, and semi-dashed line R are graphs for a blue LED, green LED, and red LED, respectively. As shown in FIG. 3, the difference in emission intensity between the blue LED and green LED is relatively small even when the temperature rises, but the emission intensity of the red LED rapidly drops as the temperature rises.

Accordingly, if the blue, green, and red LEDs are all connected in series, there arises a problem that not only does the color of emission change as the ambient temperature of the light-emitting apparatus changes, but also the service life of the light-emitting apparatus becomes short due to the use of the red LEDs. It is therefore preferable to use the red phosphor 15 without using red LEDs, and to connect the blue LEDs 11 and green LEDs 12 in series. Furthermore, as earlier described, it is preferable that LEDs that are formed from compound semiconductors based on the same materials, and that can be regarded as having substantially the same forward voltage, temperature characteristics, and service life, be used for the blue LED 11 and green LED 12, respectively.

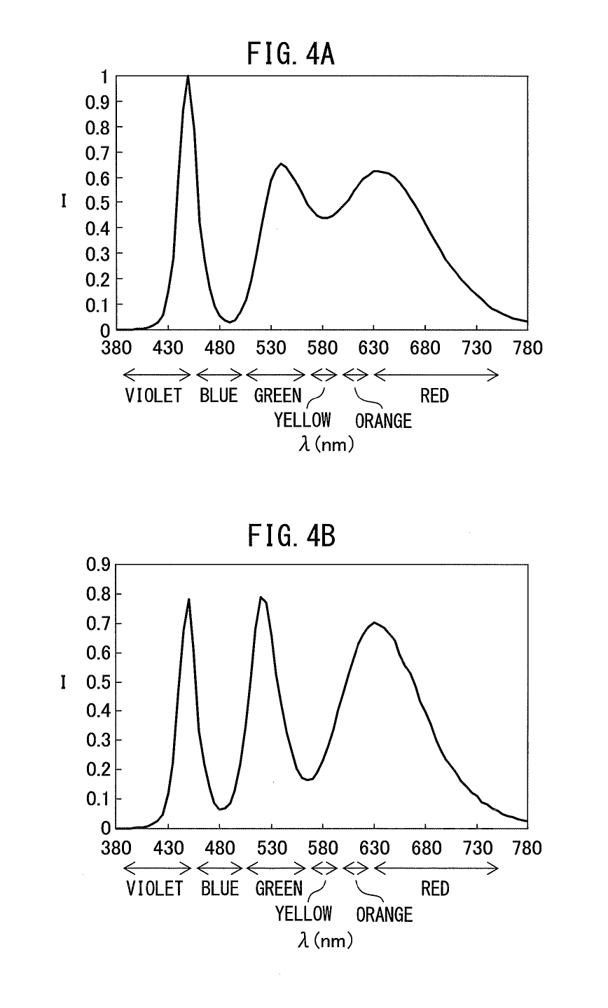

FIGS. 4A and 4B are graphs illustrating the spectrum of white light produced by a light-emitting apparatus of a comparative example and the spectrum of white light produced by the light-emitting apparatus 10, respectively. The light-emitting apparatus of the comparative example is a light-emitting apparatus which does not include green LEDs but includes blue LEDs covered with a sealing resin 13 containing green and red phosphors. In each graph, the abscissa represents the wavelength λ (nm), and the ordinate represents the relative emission intensity I. In each graph, approximate wavelength ranges for the colors from violet to red are also shown.

In the spectrum shown in FIG. 4A for the light-emitting apparatus of the comparative example, the width of the peak corresponding to the green color is relatively large. As a result, the valley between the green and red is shallow, so that light of relatively uniform intensity can be obtained over the wavelength range from green to red. This serves to enhance the color rendering properties of the light-emitting apparatus of the comparative example.

On the other hand, in the spectrum shown in FIG. 4B for the light-emitting apparatus 10, a sharp peak occurs near 520 nm which is sharper than the corresponding peak of the light-emitting apparatus of the comparative example. That is, in the case of the light-emitting apparatus 10, since the width of the peak corresponding to the green color is smaller due to the inclusion of the green LEDs 12 than in the case of the light-emitting apparatus of the comparative example, the valley between the green and red becomes deeper. As a result, in the light-emitting apparatus 10, the wavelengths corresponding to the three primary colors of light, i.e., the blue light near 450 nm, the green light near 520 nm, and the red light near 650 nm, are more distinct and, compared with the light-emitting apparatus of the comparative example, the coloring properties are enhanced, and the produced while light appears crisper.

When the white light produced by the light-emitting apparatus 10 and the white light produced by the light-emitting apparatus of the comparative example are compared using the color rendering index (CRI), a higher evaluation value can be obtained for the light-emitting apparatus of the comparative example. However, when they are compared using the color quality scale (CQS), approximately the same evaluation value can be obtained for the light-emitting apparatus 10 as that for the light-emitting apparatus of the comparative example. While CRI is an index that describes the ability of a light source to faithfully render the color of the surface of an object illuminated by the light source, CQS is an index that modifies the evaluation scale of CRI so that the evaluation value becomes higher for a change in a direction in which saturation will appear higher. When an evaluation is made using the CQS index, the evaluation of the light-emitting apparatus 10 is relatively high to reflect the enhanced coloring properties.

Further, as can be seen from FIG. 4B, the emission intensity of light in the yellow wavelength range around 580 nm is low in the case of the light-emitting apparatus 10. In view of this, the valley occurring in the spectrum between the green and red wavelength ranges may be compensated for by using a yellow phosphor, as will be described below.

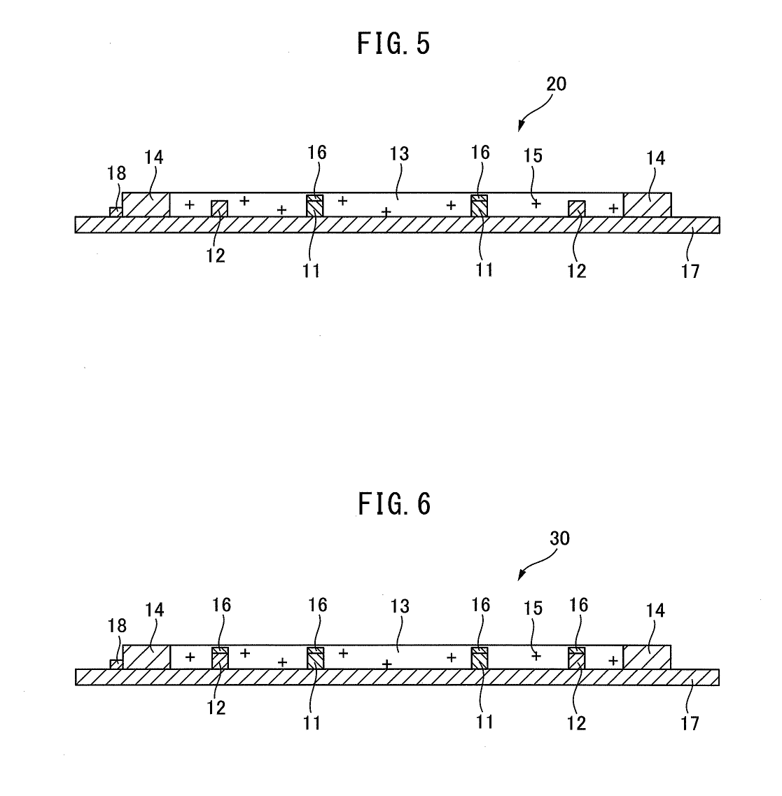

FIG. 5 is a schematic cross-sectional view of a light-emitting apparatus 20. FIG. 5 is similar to FIG. 1B, and shows a vertical cross-sectional view taken along the center line of the light-emitting apparatus 20. In the light-emitting apparatus 20, a yellow phosphor 16 is provided on each blue LED 11, and the blue LEDs 11 each provided with the yellow phosphor 16 and the green LEDs 12 are together covered with the sealing resin 13. Otherwise, the structure of the light-emitting apparatus 20 is the same as that of the light-emitting apparatus 10. In this way, the yellow phosphor 16 may be provided at least on the upper face of each blue LED 11.

The yellow phosphor 16 is a particulate phosphor material that emits yellow fluorescent light by absorbing the blue light from the corresponding blue LED 11 as pump light. For example, a phosphor based, for example, on YAG (yttrium aluminum garnet), terbium, strontium, phosphate, silicate, or aluminate, may be used as the yellow phosphor 16.

FIG. 6 is a schematic cross-sectional view of a light-emitting apparatus 30. FIG. 6 is similar to FIG. 1B, and shows a vertical cross-sectional view taken along the center line of the light-emitting apparatus 30. In the light-emitting apparatus 30, the yellow phosphor 16 is provided not only on each blue LED 11 but also on each green LED 12, and the blue LEDs 11 and green LEDs 12, each provided with the yellow phosphor 16, are together covered with the sealing resin 13. Otherwise, the structure of the light-emitting apparatus 30 is the same as that of the light-emitting apparatus 10. In this way, the yellow phosphor 16 may be provided on the upper face of every one of the LEDs.

As has been described above, in the light-emitting apparatuses 10, 20, and 30, since the plurality of blue LEDs 11 and the plurality of green LEDs 12 are respectively constructed using LEDs having substantially the same forward voltage, temperature characteristics, and service life, and are connected in series with each other, the wiring and control for lighting the respective color LEDs are further simplified. Furthermore, in the light-emitting apparatuses 10, 20, and 30, since the blue LEDs 11 and green LEDs 12 are used in combination with the red phosphor 15, the wavelengths of the blue, green, and red lights are more distinct, and thus white light that appears crisp can be obtained.

By mounting the plurality of blue LEDs 11 and green LEDs 12 in the form of an array on the substrate 17, the light-emitting apparatuses 10, 20, and 30 can each be used, for example, as a light source such as a backlight in a large-area liquid crystal display. Furthermore, the light-emitting apparatuses 10, 20, and 30 can be used as various kinds of illuminating light sources, for example, for illuminating a light conducting panel in a small-area liquid crystal display of a mobile telephone or the like, or for backlighting a meter, an indicator, or like instrument.

The preceding description has been presented only to illustrate and describe exemplary embodiments of the present invention. It is not intended to be exhaustive or to limit the invention to any precise form disclosed. It will be understood by those skilled in the art that various changes may be made and equivalents may be substituted for elements thereof without departing from the scope of the invention. In addition, many modifications may be made to adapt a particular situation or material to the teachings of the invention without departing from the essential scope. Therefore, it is intended that the invention not be limited to the particular embodiment disclosed as the best mode contemplated for carrying out this invention, but that the invention will include all embodiments falling within the scope of the claims. The invention may be practiced otherwise than is specifically explained and illustrated without departing from its spirit or scope.

What is claimed is:

1. A light-emitting apparatus comprising:
a plurality of blue-emitting devices as blue-emitting semiconductor light-emitting devices;
a plurality of green-emitting devices as green-emitting semiconductor light-emitting devices; and
a sealing resin through which is dispersed a red phosphor that emits red light by absorbing blue light from the plurality of blue-emitting devices and green light from the plurality of green-emitting devices as pump light, the sealing resin covering the plurality of blue-emitting devices and the plurality of green-emitting devices, wherein
the plurality of blue-emitting devices and the plurality of green-emitting devices are connected in series with each other.

2. The light-emitting apparatus according to claim 1, wherein the plurality of blue-emitting devices and the plurality of green-emitting devices are both InGaN-based semiconductor light-emitting devices.

3. The light-emitting apparatus according to claim 1, wherein the plurality of blue-emitting devices and the plurality of green-emitting devices are grouped into a plurality of columns which are then connected in parallel with each other on a single substrate, and wherein in each of the plurality of columns, a plurality of the blue-emitting devices and a plurality of the green-emitting devices are connected in series with each other.

4. The light-emitting apparatus according to claim 3, wherein the ratio of the number of the plurality of blue-emitting devices to the number of the plurality of green-emitting devices contained in each of the plurality of columns is the same for all of the columns.
